(19) United States
(12) Patent Application Publication
(10) Pub. No.: US 2009/0031945 A1
(43) Pub. Date: Feb. 5, 2009

(54) SINGLE CRYSTAL AND SEMICONDUCTOR WAFER AND APPARATUS AND METHOD FOR PRODUCING A SINGLE CRYSTAL

(75) Inventors: Laszlo Fabry, Burghausen (DE); Gunter Strebel, Burghausen (DE); Hans Oelkrug, Tittmoning (DE)

Correspondence Address: KOLISCH HARTWELL, P.C., 200 PACIFIC BUILDING, 520 SW YAMHILL STREET, PORTLAND, OR, 97204, US

(73) Assignee: Siltronic AG, Munich (DE)

(21) Appl. No.: 12/175,376

(22) Filed: Jul. 17, 2008

Related U.S. Application Data
(62) Division of application No. 11/655,509, filed on Jan. 18, 2007, now abandoned.

(30) Foreign Application Priority Data
Jan. 19, 2006 (DE) 10 2006 002 682.9

(51) Int. Cl. C30B 15/10

(52) U.S. Cl. 117/216; 277/650

(57) ABSTRACT

The disclosure relates to an apparatus and a method for producing a single crystal of semiconductor material. The apparatus comprises a chamber and a crucible which is arranged in the chamber and is enclosed by a crucible heater, a radiation shield for shielding a growing single crystal and thermal insulation between the crucible heater and an inner wall of the chamber. The apparatus may include a resilient seal which seals a gap between the inner wall and the thermal insulation and forms an obstacle for the transport of gaseous iron carbonyls to the single crystal. The disclosure also relates to a method for producing a single crystal of semiconductor material by using the apparatus, the single crystal which is produced and a semiconductor wafer cut therefrom. The single crystal and the semiconductor wafer are distinguished by an edge region, which extends from the circumference to a distance of up to R-5 mm radially into the single crystal or the semiconductor wafer and has an iron concentration, wherein the iron concentration in the edge region is less than 1*10⁹ atoms/cm³.

### RELATED APPLICATIONS

The present application is a division of application Ser. No. 11/655,509, filed Jan. 18, 2007, which application is incorporated herein by reference in its entirety for all purposes. The present application claims the benefit of German Patent Application, Serial No. 10 2006 002 682.9, filed on Jan. 19, 2006, the complete disclosure of which is hereby incorporated by reference herein in its entirety and for all purposes.

### FIELD OF THE DISCLOSURE

The disclosure relates to an apparatus for producing a single crystal of semiconductor material, which is contaminated only slightly by iron. The disclosure also relates to a method for producing such a single crystal. The disclosure furthermore relates to a single crystal of semiconductor material produced by the method and to a semiconductor wafer cut from the single crystal.

### BACKGROUND OF THE DISCLOSURE

A suitable apparatus includes a crucible in a chamber. The crucible is embedded in a support crucible made of material containing carbon. The apparatus also includes a heater for heating the crucible and thermal insulation, which is arranged between the heater and the crucible in order to protect the chamber. The apparatus also typically includes a radiation shield that encloses the growing crystal and serves to control the cooling rate of the single crystal and to deflect an inert gas with which the apparatus is flushed during production of the single crystal.

According to JP-2000327485 A, which is incorporated herein by reference for all purposes, it is possible to produce single crystals of silicon in which the iron concentration is less than 2*10⁹ atoms/cm³. In order to produce such single crystals, it is necessary to purify the polycrystalline intermediate product in an elaborate process. Said concentration, however, is still not a sufficient feature for a single crystal which is contaminated only slightly with iron in the context of the disclosure. Rather, what is desired is that there is also a low iron concentration in the edge region of the single crystal. As Barraclough, K. G. and Ward, P. J. (Proc. Electrochem. Soc., 83-9, 388-395 (1983), which is incorporated herein by reference for all purposes) have observed, iron reaches the edge of the single crystal via a mechanism which is based on gas phase transport, diffuses from there into the single crystal and significantly increases the iron concentration in the edge region of the single crystal. In order to counteract this, it has been proposed in the document inter alia to replace a holder consisting of stainless steel for the seed crystal by a holder made of molybdenum.

According to WO 02/057518 A2, which is incorporated herein by reference for all purposes, it is possible to produce single crystals of silicon in which the iron concentration in an edge region is less than 0.8 ppta (3.99*10¹⁰ atoms/cm³). In order to achieve this result, all components of the apparatus that consist of material containing carbon must contain this material in a particularly low-iron form, and this material must be encapsulated by a likewise particularly low-iron layer of silicon carbide.

In WO 01/81661 A1, which is incorporated herein by reference for all purposes, it is proposed to use a coated tube for directing the inert gas stream, in which case the coating should contain at most 0.5 ppm iron. According to the method described there, it is possible to produce monocrystalline semiconductor wafers of silicon in which the iron concentration is not more than 1*10¹⁰ atoms/cm³.

### BRIEF DESCRIPTION OF THE DRAWING

The FIGURE is a cross-sectional view of an embodiment of the present disclosure, showing a chamber with a crucible and a mechanism for pulling a single crystal from a melt, a radiation shield, a support crucible on a shaft, a crucible heater, thermal insulation on an inner wall of the chamber, a gap between the insulation and wall, and a seal.

The present disclosure describes how to provide an economical alternative by which it is possible to produce a single crystal of semiconductor material with an iron concentration which is not more than 1*10⁹ atoms/cm³, and which concentration is not exceeded even in the edge region of the single crystal and in the edge region of wafers cut from the single crystal.

The disclosure relates to an apparatus for producing a single crystal of semiconductor material, including a chamber and a crucible disposed in the chamber where the crucible is enclosed by a crucible heater. The disclosure further relates to a radiation shield for shielding a growing single crystal and thermal insulation between the crucible heater and an inner wall of the chamber. The apparatus may also include a resilient seal which seals a gap between the inner wall and the thermal insulation and forms an obstacle for the transport of gaseous iron carbonyls to the single crystal.

The disclosure also relates to a method for producing a single crystal of semiconductor material by pulling the single crystal from a crucible, which is arranged in a chamber and is enclosed by a crucible heater, wherein a gap between thermal insulation and an inner wall of the chamber is sealed with a resilient seal, which forms an obstacle for the transport of gaseous iron carbonyls to the single crystal.

The disclosure furthermore relates to a single crystal of semiconductor material produced according to said method, comprising a section of cylindrical shape which has a circumference, a radius R and an edge region extending from the circumference to a distance of up to R-5 mm radially into the single crystal and has an iron concentration, wherein the iron concentration in the edge region is less than 1*10⁹ atoms/cm³.

The disclosure lastly relates to a semiconductor wafer cut from the single crystal having a circumference, a radius R and an edge region extending from the circumference to a distance of up to R-5 mm radially into the semiconductor wafer and has an iron concentration, wherein the iron concentration in the edge region is less than 1*10⁹ atoms/cm³.

The semiconductor material is preferably silicon, optionally in combination with germanium, optoelectronic, and/or magnetoelectronic semiconductor compounds. The disclosed method can be used irrespective of the diameter of the single crystal produced, or of the semiconductor wafer produced. Nevertheless, diameters of 150 mm, 200 mm and 300 mm or more are particularly preferred.

A main source of the contamination of the single crystal with iron is believed to be the chamber, which is usually formed of a cooled container whose walls consist of an alloy containing iron, for example, stainless steel. It is suspected that carbon monoxide that is formed by the heating of carbon-containing components of the chamber, particularly the support crucible and the thermal insulation, reaches the inner wall of the chamber via the inert gas stream and by diffusion. At the inner wall which is still at a temperature of more than 100° C., volatile iron carbonyls form and may enter the gap between the thermal insulation and the inner wall of the chamber and reach the growing single crystal. Upon contact with the single crystal, which is at a temperature of several hundred degrees Celsius, the iron carbonyls decompose into elementary iron and carbon monoxide in reverse of the reaction by which they are formed. At the prevailing temperatures, the iron diffuses into the peripheral regions of the single crystal where it increases the iron concentration. By this mechanism, iron is also distributed over components of the apparatus which are hot enough to cause decomposition of the iron carbonyls. These include for example the support crucible, the thermal insulation for protecting the chamber and the radiation shield.

The measures previously proposed for reducing the contamination of the single crystal by iron do not take the chamber wall into account as a contamination source, and they do not provide an economically satisfactory solution to the issues.

According to the present disclosure, the gap between the thermal insulation and the wall of the chamber is closed by a resilient seal at least at one position, so that gaseous iron carbonyls must overcome this obstacle in order to be able to travel up along the inner wall of the chamber and subsequently reach the single crystal. Owing to manufacturing tolerances, the gap between the thermal insulation and the inner wall of the chamber exists even when the thermal insulation is made with a tight fit. It is, however, more customary to provide the gap deliberately in order to allow thermal expansion of the thermal insulation and the means for fastening it allow the necessary space for this expansion movement.

The seal to be provided according to the disclosure is resiliently deformable and fitted into the gap so that the gap remains closed even in view of thermal expansion. The seal may extend over the entire gap, i.e. completely fill the gap. If only for economic reasons, however, less sealing material may be used, so that the gap at least partially remains. The seal may be formed as a ring that may extend over an axial width of from 50 to 200 mm, for example about 100 mm, in which case a plurality of such rings may also be arranged above one another. In principle, however, it is desired for the seal to form an obstacle extending transversely to the axis of the single crystal, which limits the transport of gaseous iron carbonyls along the inner wall of the chamber to the single crystal. The transport may be regarded as having been limited when the iron concentration in the edge region of a single crystal, which has been produced by using the seal, is at least 50% lower than in a single crystal which was pulled under otherwise equal conditions but whose production did not employ the seal. Instead of the iron concentration in the edge region of the single crystal, it is also possible to refer to the concentration in the edge region of a semiconductor wafer cut from the single crystal. The edge region is a region which extends radially inwards over a distance of preferably up to 5 mm from the circumference of the single crystal, or of a semiconductor wafer cut therefrom. The iron concentration may be measured at a position which lies at a radial distance of 1, 2, 3, 4 or 5 mm from the circumference.

The seal consists of a resilient material, for example graphite felt, which contains carbonized or graphitized carbon fibers. The material may be resilient enough to be wound in one layer around a test rod with a diameter of from 50 to 80 mm without breaking, with a winding direction transverse to or along the material web. The breaking strain of the material according to DIN 52143 typically is from 2 to 5% along and from 13 to 20% transversely to the material web. The gas permeability of the material according to DIN 53887 typically is from 25 to 50 cm³/(cm²*s), with a pressure difference of 300 Pa in nitrogen. The iron content of the material according to DIN ISO 8658 is typically less than 0.3 mg/kg. Graphite felt of the brand Sigratherm® GFA 10 from the manufacturer SGL Carbon may be used. This material is available in the form of webs with a thickness of 9-10 mm. The material may be arranged in multiple layers or in a folded state to form a labyrinth seal suitable for sealing a gap between the inner wall of the chamber and the thermal insulation which is thicker than the thickness of a web.

An additional measure which is proposed in order to achieve the results described above consists in providing the inner wall of the chamber with a ceramic coating. A coating of aluminum oxide may be used. The coating prevents direct contact of carbon monoxide and the inner wall of the chamber, and thus reduces the formation of iron carbonyls.

A further measure, which may be taken in combination with the resilient seal and the ceramic coating or only in combination with the resilient seal, consists in providing an active cooling system for cooling the single crystal. The term active cooling system is intended to mean cooling components which extract heat by using supplied energy, for example components which operate according to the heat exchanger principle. Active cooling systems are also used to control the defect formation in silicon crystals, for example, and may be part of the conventionally provided radiation shield which encloses the growing single crystal. The cooling systems may contribute to achieving the results described herein by providing temperatures on the surface of the growing single crystal, and in its environment, at which iron carbonyls can no longer thermally decompose. An example of a suitable active cooling system, which is integrated into a radiation shield, is described in U.S. Pat. No. 5,567,399, which is incorporated herein by reference for all purposes.

As a further additional measure, it is lastly proposed that the thermal insulation and all other components made of material containing carbon, which are located in the chamber and are heated to temperatures of more than 200° C. during the production of the single crystal, be replaced at regular intervals. These components may optionally be reused, after deposited iron has been cleaned from their surfaces.

An embodiment of the disclosure will be explained in more detail below with reference to a FIGURE. The FIGURE schematically shows an apparatus for producing a single crystal of semiconductor material according to the Czochralski method, the representation being limited to showing those features which contribute to understanding of the disclosure. Bold, solid arrows symbolize the primary direction of an inert gas stream conventionally used for flushing the chamber. Broken arrows symbolize the path by which iron carbonyls can reach the single crystal, if they are not prevented from doing so according to the present disclosure. The apparatus comprises a chamber 1 in which a crucible 2 and further components, which fulfill functions during the production of a single crystal 3, are fitted. These components include a mechanism 4 for pulling the single crystal 3 from a melt 5 which is contained in the crucible 2, a support crucible 7 arranged on a shaft 6 in order to hold the crucible 2, and a crucible heater 8 surrounding the crucible. The inner wall 9 of the chamber is protected by thermal insulation 10 against the heat given off by the crucible heater 8. Thermal insulation may also be provided in the form of further components at other positions, for example insulation in the region of the shaft 6 and the bottom region of the chamber. Between the thermal insulation 10 and the inner wall 9 of the chamber, there is a gap 11 which is closed by a resilient seal 12. According to an embodiment, the seal 12 is designed as a ring. The growing single crystal 3 is surrounded by a radiation shield 13 that may itself include thermally insulating elements, and which is fastened on a support 16. According to another embodiment, an active cooling system 14 may cool the single crystal in addition to the radiation shield or the cooling system may be integrated into the radiation shield.

According to another embodiment, the inner wall 9 of the chamber may be provided with a ceramic coating 15, which prevents carbon monoxide and iron from the wall material reacting to form iron carbonyls. The coating 15 is represented only indicatively in the FIGURE, and typically covers at least a substantial portion of the inner wall.

### EXAMPLE

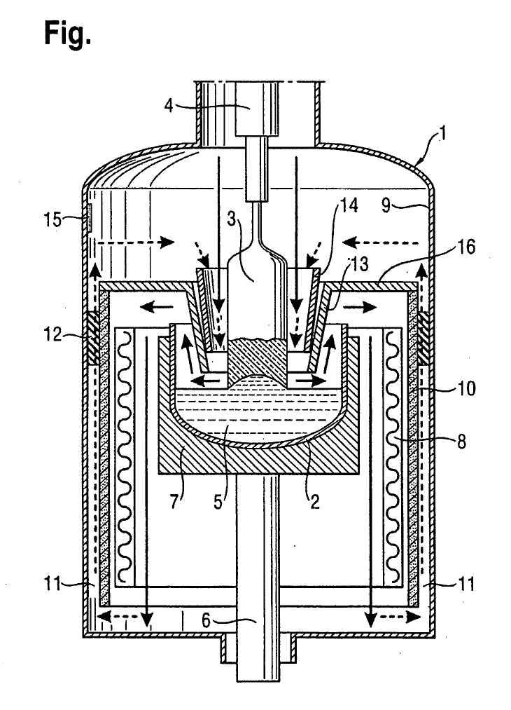

In an apparatus for pulling single crystals having the features of the installation outlined in FIG. 1, without a coating 15 of the inner wall 9 but with a resilient seal 12 designed as a ring with an axial width of about 100 mm, rod-shaped single crystals of silicon with a diameter of 200 mm were pulled and the iron concentration was determined in the edge region of wafers, which were cut from the single crystals. The wafers measured were taken from the same axial rod position. Type A wafers came from single crystals which were produced with the apparatus, the resilient seal according to the disclosure not having been used. The single crystals which gave type B wafers were produced in the same apparatus, but with the difference that the gap between the inner wall of the chamber and the thermal insulation was sealed by the ring of Sigratherm® GFA 10 type graphite felt extending transversely to the axis of the single crystal. An active cooling system, which was integrated into the radiation shield, was used in addition to the resilient seal in order to produce the single crystals which gave type C wafers. The results of the iron concentration determinations at three positions with radial distances of 1 mm, 3 mm and 5 mm from the edge R of the wafers are collected in the following table. The iron concentration outside the edge region was in no case higher than in the edge region. The concentrations were determined according to ASTM F 391.

TABLE

| | Position R-1 mm | Position R-3 mm | Position R-5 mm |
|---|---|---|---|
| Type | Fe [atoms/cm³] | Fe [atoms/cm³] | Fe [atoms/cm³] |
| A | 3*10¹⁰ | 2.3*10¹⁰ | 1.3*10¹⁰ |
| B | 1.5*10¹⁰ | 1*10¹⁰ | 0.6*10¹⁰ |
| C | <LoD | <LoD | <LoD |

The results show that the iron concentration could be reduced by at least 50% by providing the seal. The iron concentration at the positions studied in type C wafers actually lay below the limit of detection (LoD), which is 1*10⁹ atoms/cm³.

1. An apparatus for producing a single crystal of semiconductor material, the apparatus comprising:
a chamber defining an inner wall;
a crucible disposed in the chamber;
a crucible heater substantially surrounding the crucible;
a radiation shield configured to shield the single crystal;
thermal insulation disposed between the crucible heater and the inner wall of the chamber, the thermal insulation and the inner wall defining a gap therebetween; and
a resilient seal that substantially seals the gap between the inner wall and the thermal insulation.

2. The apparatus of claim 1, wherein the seal forms an obstacle against a transport of gaseous iron carbonyls to the single crystal and the seal reduces the transport of the gaseous iron carbonyls to the single crystal by at least about 50%.

3. The apparatus of claim 1, wherein the resilient seal is substantially ring-shaped.

4. The apparatus of claim 1 wherein the resilient seal allows for a thermal expansion of the thermal insulation.

5. The apparatus of claim 1, wherein the seal includes a graphite felt.

6. The apparatus of claim 5 wherein the graphite felt includes carbon fibers.

7. The apparatus of claim 1 further comprising an active cooling system for cooling the single crystal.

8. The apparatus of claim 1 further comprising a ceramic coating on the inner wall of the chamber.

9. A seal for use in an apparatus for producing a single crystal of semiconductor material, the apparatus including a chamber defining an inner wall, a crucible disposed in the chamber, a crucible heater substantially surrounding the crucible, a radiation shield for shielding the single crystal, and thermal insulation disposed between the crucible heater and the inner wall of the chamber, the thermal insulation and the inner wall defining a gap therebetween, the seal comprising:
a resilient material that seals the gap between the inner wall and the thermal insulation, the resilient material providing a substantial obstacle against transport of gaseous iron carbonyls to the single crystal.

10. A system for reducing transport of gaseous iron carbonyls to a single crystal in a crystal-growing apparatus, the apparatus including a chamber defining an inner wall, a crucible disposed in the chamber, a crucible heater substantially surrounding the crucible, a radiation shield for shielding the single crystal, and thermal insulation disposed between the crucible heater and the inner wall of the chamber, the thermal insulation and the inner wall defining a gap therebetween, the system comprising:
a resilient seal disposed in the gap between the inner wall and the thermal insulation; and
an active cooling system disposed adjacent the single crystal to cool the single crystal during growth.
